(19) United States
(12) Patent Application Publication
(10) Pub. No.: US 2015/0185548 A1
(43) Pub. Date: Jul. 2, 2015

(54) TFT SUBSTRATE AND LIQUID CRYSTAL DISPLAY PANEL USING SAME

(71) Applicant: Shenzhen China Star Optoelectronics Technology Co. Ltd., Shenzhen, Guangdong (CN)

(72) Inventors: Hongyuan Xu, Shenzhen City (CN); Hsiangchih Hsiao, Shenzhen City (CN); Changi Su, Shenzhen City (CN); Mian Zeng, Shenzhen City (CN); Xiaoxiao Wang, Shenzhen City (CN)

(21) Appl. No.: 14/241,075

(22) PCT Filed: Jan. 21, 2014
(86) PCT No.: PCT/CN2014/070937

§ 371 Date: Feb. 25, 2014

(30) Foreign Application Priority Data
Dec. 26, 2013 (CN) 201310733604.2

(51) Int. Cl. G02F 1/1335; H01L 29/786; H01L 27/12

(52) U.S. Cl. CPC G02F 1/133514; H01L 27/124; H01L 29/78669; H01L 27/1255

(57) ABSTRACT

The present invention provides a TFT substrate and a liquid crystal display panel using the TFT substrate. The TFT substrate includes: first and second sharing capacitors (2, 4) that are connected in parallel. The first sharing capacitor (2) includes a first upper substrate (22), a first lower substrate (24) opposite to the first upper substrate (22), and a first semiconductor layer (26) arranged between the first upper substrate (22) and the first lower substrate (24). The second sharing capacitor (4) includes a second upper substrate (42), a second lower substrate (44) opposite to the second upper substrate (42), and a second semiconductor layer (46) arranged between the second upper substrate (42) and the second lower substrate (44). The first upper substrate (22) of the first sharing capacitor (2) and the second lower substrate (44) of the second sharing capacitor (4) are electrically connected to the pixel electrode (6). The second upper substrate (42) of the second sharing capacitor (4) is electrically connected to the Com trace (8).

### BACKGROUND OF THE INVENTION

1. Field of the Invention

The present invention relates to the field of flat panel displaying, and in particular to a TFT (Thin-Film Transistor) substrate and a liquid crystal display panel using the TFT substrate.

2. The Related Arts

Liquid crystal displays (LCDs) have a variety of advantages, such as thin device body, low power consumption, and being free of radiation, and are thus of wide applications, such as mobile phones, personal digital assistants (PDAs), digital cameras, computer monitors, and notebook computer screens.

Most of the liquid crystal displays that are currently available in the market are backlighting liquid crystal displays, which comprise an enclosure, a liquid crystal display panel arranged in the enclosure, and a backlight module mounted in the enclosure. The structure of a conventional liquid crystal display panel is composed of a color filter (CF) substrate, a thin-film transistor (TFT) array substrate, and a liquid crystal layer arranged between the two substrates and the principle of operation is that a driving voltage is applied to the two glass substrates to control rotation of the liquid crystal molecules of the liquid crystal layer in order to refract out light emitting from the backlight module for generating images. Since the liquid crystal display panel itself does not emit light, light must be provided from the backlight module in order to normally display images. Thus, the backlight module is one of the key components of the liquid crystal displays. The backlight modules can be classified in two types, namely a side-edge backlight module and a direct backlight module, according to the site where light gets incident. The direct backlight module comprises a light source, such as a cold cathode fluorescent lamp (CCFL) or a light-emitting diode (LED), which is arranged at the backside of the liquid crystal display panel to form a planar light source directly supplied to the liquid crystal display panel. The side-edge backlight module comprises an LED light bar, serving as a backlight source, which is arranged at an edge of a backplane to be located rearward of one side of the liquid crystal display panel. The LED light bar emits light that enters a light guide plate (LGP) through a light incident face at one side of the light guide plate and is projected out of a light emergence face of the light guide plate, after being reflected and diffused, to pass through an optic film assembly so as to form a planar light source for the liquid crystal display panel.

LCDs have various displaying modes, of which VA (Vertical Alignment) is a commonly used displaying mode that has various advantages including high contrast, wide view angle, and no need of rubbing alignment. Since the VA displaying mode uses vertically rotating liquid crystal, it suffers color washout at large view angles. To cope with such a problem, a commonly adopted arrangement is to divide a pixel area into a main zone and a sub-zone for displaying. The main zone and sub-zone apply different voltages to two sides of the liquid crystal so as to make the liquid crystal rotating by different angles at the main zone and the sub-zone thereby overcoming the issue of color washout.

To provide different pixel voltages to the main zone and the sub-zone, a common arrangement is connecting a sharing capacitor C (circled with phantom lines in FIG. 2) in series to a pixel electrode of the sub-zone so that the capacitor can pull down the potential of the pixel electrode of the sub-zone. However, in a commonly used 4-mask manufacturing process, the sharing capacitor C can only be made in a structure of metal insulation semiconductor (MIS). The capacitor of the MIS structure interposes therein a layer of semiconductor (see FIG. 1), of which an equivalent circuit is shown in FIG. 2. This makes the magnitude of the sharing capacitor C varying when voltages of upper and lower substrates vary in positive and negative frames. This leads to the pixel voltages of positive and negative frames being unsymmetrical and flickering may result. Further, the pixel voltages of positive and negative frames being unsymmetrical also cause a direct current biasing voltage at two ends of the liquid crystal, resulting in image sticking in a liquid crystal panel and thus affecting the quality and reliability of the panel.

### SUMMARY OF THE INVENTION

An object of the present invention is to provide a TFT (Thin-Film Transistor) substrate, which has a simple structure and is capable of compensating differences of capacitance in positive and negative frames so as to achieve that total capacitance can maintain constant in positive and negative frames.

Another object of the present invention is to provide a liquid crystal display panel, which effectively overcomes flickering of liquid crystal display panel, reduces direct current biasing voltage, and improves image sticking phenomenon.

To achieve the above objects, the present invention provides a TFT substrate, which comprises: first and second sharing capacitors that are connected in parallel, a pixel electrode, and a Com trace, wherein the first sharing capacitor comprises a first upper substrate, a first lower substrate opposite to the first upper substrate, and a first semiconductor layer between the first upper substrate and the first lower substrate; the second sharing capacitor comprises a second upper substrate, a second lower substrate opposite to the second upper substrate, and a second semiconductor layer between the second upper substrate and the second lower substrate; the first upper substrate of the first sharing capacitor and the second lower substrate of the second sharing capacitor are electrically connected to the pixel electrode; and the second upper substrate of the second sharing capacitor is electrically connected to the Com trace.

The first upper substrate and the second upper substrate are formed of metal at the same time and the first lower substrate, the second lower substrate, and the Com trace are formed of metal at the same time.

The first semiconductor layer and the second semiconductor layer are formed at the same time and the first semiconductor layer and the second semiconductor layer both comprise a gate insulation layer and an amorphous silicon layer.

The pixel electrode is formed of nanometer indium tin oxide and the first upper substrate, the second lower substrate, and the pixel electrode are electrically connected by nanometer indium tin oxide.

The second upper substrate and the Com trace are electrically connected by nanometer indium tin oxide.

The present invention also provides a TFT substrate, which comprises: first and second sharing capacitors that are connected in parallel, a pixel electrode, and a Com trace, wherein the first sharing capacitor comprises a first upper substrate, a first lower substrate opposite to the first upper substrate, and a first semiconductor layer between the first upper substrate and the first lower substrate; the second sharing capacitor comprises a second upper substrate, a second lower substrate opposite to the second upper substrate, and a second semiconductor layer between the second upper substrate and the second lower substrate; the first upper substrate of the first sharing capacitor and the second lower substrate of the second sharing capacitor are electrically connected to the pixel electrode; and the second upper substrate of the second sharing capacitor is electrically connected to the Com trace; and

wherein the first upper substrate and the second upper substrate are formed of metal at the same time and the first lower substrate, the second lower substrate, and the Com trace are formed of metal at the same time.

The first semiconductor layer and the second semiconductor layer are formed at the same time and the first semiconductor layer and the second semiconductor layer both comprise a gate insulation layer and an amorphous silicon layer.

The pixel electrode is formed of nanometer indium tin oxide and the first upper substrate, the second lower substrate, and the pixel electrode are electrically connected by nanometer indium tin oxide.

The second upper substrate and the Com trace are electrically connected by nanometer indium tin oxide.

The present invention further provides a liquid crystal display panel, which comprises: a TFT substrate, a CF substrate opposite to and laminated to the TFT substrate, and a liquid crystal layer arranged between the TFT substrate and the CF substrate, wherein the TFT substrate comprises first and second sharing capacitors that are connected in parallel, a pixel electrode, and a Com trace; the first sharing capacitor comprises a first upper substrate, a first lower substrate opposite to the first upper substrate, and a first semiconductor layer between the first upper substrate and the first lower substrate; the second sharing capacitor comprises a second upper substrate, a second lower substrate opposite to the second upper substrate, and a second semiconductor layer between the second upper substrate and the second lower substrate; the first upper substrate of the first sharing capacitor and the second lower substrate of the second sharing capacitor are electrically connected to the pixel electrode; and the second upper substrate of the second sharing capacitor is electrically connected to the Com trace.

The first upper substrate and the second upper substrate are formed of metal at the same time and the first lower substrate, the second lower substrate, and the Com trace are formed of metal at the same time.

The first semiconductor layer and the second semiconductor layer are formed at the same time and the first semiconductor layer and the second semiconductor layer both comprise a gate insulation layer and an amorphous silicon layer.

The pixel electrode is formed of nanometer indium tin oxide and the first upper substrate, the second lower substrate, and the pixel electrode are electrically connected by nanometer indium tin oxide.

The second upper substrate and the Com trace are electrically connected by nanometer indium tin oxide.

The efficacy of the present invention is that the present invention provides a TFT substrate and a liquid crystal display panel using the TFT substrate, in which the first and second sharing capacitors are provided in parallel connection with each other so as to maintain total capacitance constant in positive and negative frames thereby reducing pixel voltage asymmetry in positive and negative frames, reducing direct current biasing voltage, and suppressing the image sticking phenomenon.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a schematic view showing the structure of a conventional sharing capacitor;

FIG. 2 shows an equivalent circuit of a TFT (Thin-Film Transistor) substrate using the conventional sharing capacitor;

FIG. 3 is a schematic view showing the structure of a TFT substrate according to the present invention;

FIG. 4 is an equivalent circuit of the TFT substrate of the present invention;

FIG. 5 is plots showing individual capacitance-voltage curves of a first and a second sharing capacitors of the TFT substrate of the present invention;

FIG. 6 is a plot showing a total capacitance-voltage curve of the first and second sharing capacitors of the TFT substrate of the present invention; and

FIG. 7 is a cross-sectional view showing the structure of a liquid crystal display panel according to the present invention.

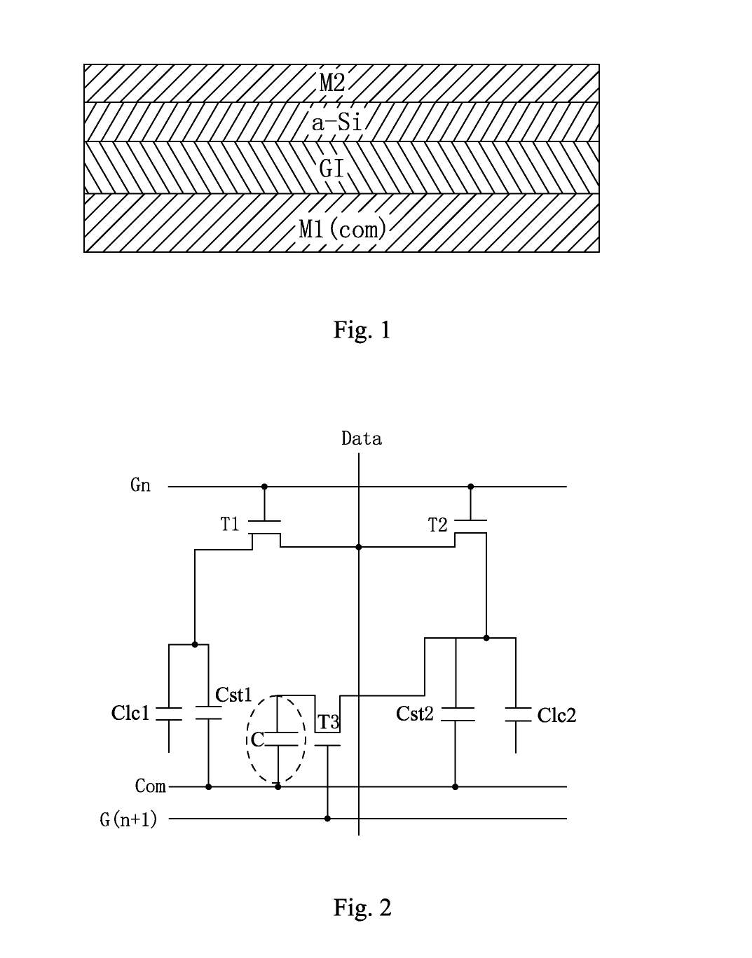

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

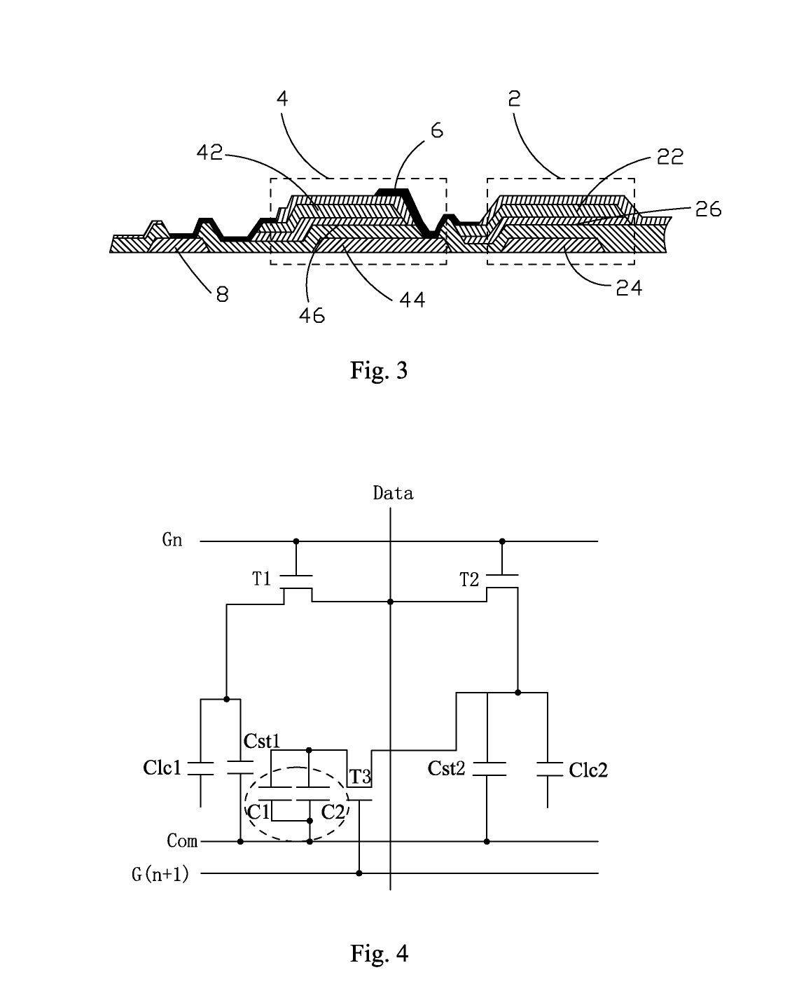

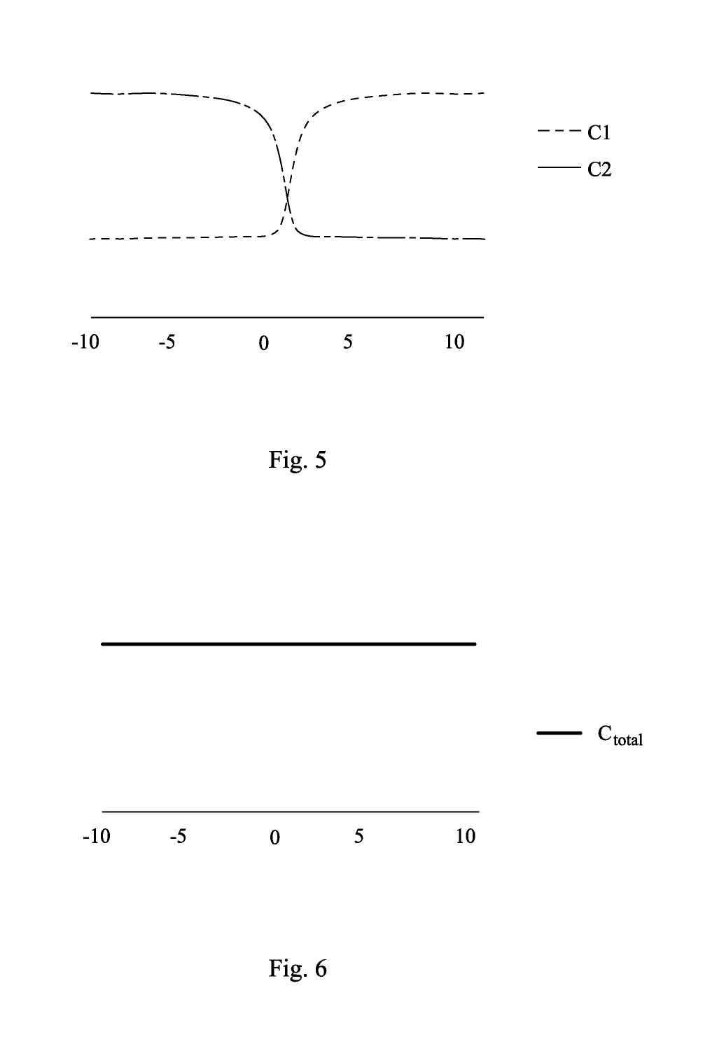

Referring to FIGS. 3-6, the present invention provides a TFT (Thin-Film Transistor) substrate, which comprises: first and second sharing capacitors 2, 4 that are connected in parallel, a pixel electrode 6, and a Com trace 8. The first sharing capacitor 2 comprises a first upper substrate 22, a first lower substrate 24 opposite to the first upper substrate 22, and a first semiconductor layer 26 between the first upper substrate 22 and the first lower substrate 24. The second sharing capacitor 4 comprises a second upper substrate 42, a second lower substrate 44 opposite to the second upper substrate 42, and a second semiconductor layer 46 between the second upper substrate 42 and the second lower substrate 44. The first upper substrate 22 of the first sharing capacitor 2 and the second lower substrate 44 of the second sharing capacitor 4 are electrically connected to the pixel electrode 6. The second upper substrate 42 of the second sharing capacitor 4 is electrically connected to the Com trace 8. When a signal line feeds in a positive frame signal, the first upper substrate 22 of the first sharing capacitor 2 is at a high level and the first lower substrate 24 is at a low level; at the same time, the second upper substrate 42 of the second sharing capacitor 4 is at a low level and the second lower substrate 44 is at a high level. When the signal line is of a negative frame signal, the first upper substrate 22 of the first sharing capacitor 2 is at a low level and the first lower substrate 24 is at a high level; at the same time, the second upper substrate 42 of the second sharing capacitor 4 is at a high level and the second lower substrate 44 is at a low level. Capacitances of the first sharing capacitor 2 and the second sharing capacitor 4 varying with difference of voltage are illustrated in FIG. 5. The capacitances of the first sharing capacitor 2 and the second sharing capacitor 4 vary with the variation of voltage difference, but since the first sharing capacitor 2 and the second sharing capacitor 4 are of opposite potentials, when the capacitance of the first sharing capacitor 2 increases, the capacitance of the second sharing capacitor 4 decreases and when the capacitance of the first sharing capacitor 2 decreases, the capacitance of the second sharing capacitor 4 increases, whereby the total capacitance Cₜₒₜₐₗ (circled by phantom lines in FIG. 4) of the first sharing capacitor 2 and the second sharing capacitor 4 can maintain constant (as shown in FIG. 6).

Specifically, the first upper substrate 22 and the second upper substrate 42 are formed of metal at the same time and the first lower substrate 24, the second lower substrate 44, and the Com trace 8 are formed of metal at the same time, meaning being formed simultaneously with a gate terminal (not shown) by a first metal layer (M1) through one round of photolithographic process.

The first semiconductor layer 26 and the second semiconductor layer 46 are formed at the same time and the first semiconductor layer 26 and the second semiconductor layer 46 both comprises a gate insulation (GI) layer and an amorphous silicon (a-Si) layer.

The pixel electrode 6 is formed of nanometer indium tin oxide (ITO). The first upper substrate 22, the second lower substrate 44, and the pixel electrode 6 are electrically connected by nanometer indium tin oxide.

The second upper substrate 42 and the Com trace 8 are connected by nanometer indium tin oxide.

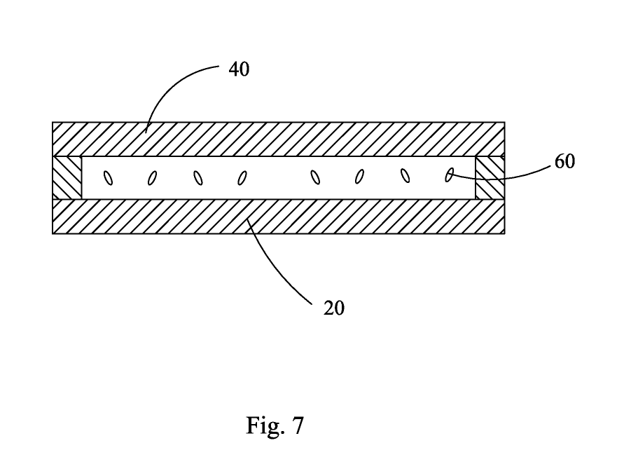

Referring to FIGS. 7, with additional reference to FIGS. 3-6, the present invention also provides a liquid crystal display panel, which comprises: a TFT substrate 20, a CF (Color Filter) substrate 40 opposite to and laminated to the TFT substrate 20, and a liquid crystal layer 60 arranged between the TFT substrate 20 and the CF substrate 40. The TFT substrate 20 comprises first and second sharing capacitors 2, 4 that are connected in parallel, a pixel electrode 6, and a Com trace 8. The first sharing capacitor 2 comprises a first upper substrate 22, a first lower substrate 24 opposite to the first upper substrate 22, and a first semiconductor layer 26 between the first upper substrate 22 and the first lower substrate 24. The second sharing capacitor 4 comprises a second upper substrate 42, a second lower substrate 44 opposite to the second upper substrate 42, and a second semiconductor layer 46 between the second upper substrate 42 and the second lower substrate 44. The first upper substrate 22 of the first sharing capacitor 2 and the second lower substrate 44 of the second sharing capacitor 4 are electrically connected to the pixel electrode 6. The second upper substrate 42 of the second sharing capacitor 4 is electrically connected to the Com trace 8. When a signal line feeds in a positive frame signal, the first upper substrate 22 of the first sharing capacitor 2 is at a high level and the first lower substrate 24 is at a low level; at the same time, the second upper substrate 42 of the second sharing capacitor 4 is at a low level and the second lower substrate 44 is at a high level. When the signal line is of a negative frame signal, the first upper substrate 22 of the first sharing capacitor 2 is at a low level and the first lower substrate 24 is at a high level; at the same time, the second upper substrate 42 of the second sharing capacitor 4 is at a high level and the second lower substrate 44 is at a low level. Capacitances of the first sharing capacitor 2 and the second sharing capacitor 4 varying with difference of voltage are illustrated in FIG. 5. The capacitances of the first sharing capacitor 2 and the second sharing capacitor 4 vary with the variation of voltage difference, but since the first sharing capacitor 2 and the second sharing capacitor 4 are of opposite potentials, when the capacitance of the first sharing capacitor 2 increases, the capacitance of the second sharing capacitor 4 decreases and when the capacitance of the first sharing capacitor 2 decreases, the capacitance of the second sharing capacitor 4 increases, whereby the total capacitance Cₜₒₜₐₗ (circled by phantom lines in FIG. 4) of the first sharing capacitor 2 and the second sharing capacitor 4 can maintain constant (as shown in FIG. 6).

Specifically, the first upper substrate 22 and the second upper substrate 42 are formed of metal at the same time and the first lower substrate 24, the second lower substrate 44, and the Com trace 8 are formed of metal at the same time, meaning being formed simultaneously with a gate terminal (not shown) by a first metal layer (M1) through one round of photolithographic process.

The first semiconductor layer 26 and the second semiconductor layer 46 are formed at the same time and the first semiconductor layer 26 and the second semiconductor layer 46 both comprises a gate insulation (GI) layer and an amorphous silicon (a-Si) layer.

The pixel electrode 6 is formed of nanometer indium tin oxide (ITO). The first upper substrate 22, the second lower substrate 44, and the pixel electrode 6 are electrically connected by nanometer indium tin oxide.

The second upper substrate 42 and the Com trace 8 are connected by nanometer indium tin oxide.

In summary, the present invention provides a TFT substrate and a liquid crystal display panel using the TFT substrate, in which the first and second sharing capacitors are provided in parallel connection with each other so as to maintain total capacitance constant in positive and negative frames thereby reducing pixel voltage asymmetry in positive and negative frames, reducing direct current biasing voltage, and suppressing the image sticking phenomenon.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A TFT (Thin-Film Transistor) substrate, comprising: first and second sharing capacitors that are connected in parallel, a pixel electrode, and a Com trace, wherein the first sharing capacitor comprises a first upper substrate, a first lower substrate opposite to the first upper substrate, and a first semiconductor layer between the first upper substrate and the first lower substrate; the second sharing capacitor comprises a second upper substrate, a second lower substrate opposite to the second upper substrate, and a second semiconductor layer between the second upper substrate and the second lower substrate; the first upper substrate of the first sharing capacitor and the second lower substrate of the second sharing capacitor are electrically connected to the pixel electrode; and the second upper substrate of the second sharing capacitor is electrically connected to the Com trace.

2. The TFT substrate as claimed in claim 1, wherein the first upper substrate and the second upper substrate are formed of metal at the same time and the first lower substrate, the second lower substrate, and the Com trace are formed of metal at the same time.

3. The TFT substrate as claimed in claim 1, wherein the first semiconductor layer and the second semiconductor layer are formed at the same time and the first semiconductor layer and the second semiconductor layer both comprise a gate insulation layer and an amorphous silicon layer.

4. The TFT substrate as claimed in claim 1, wherein the pixel electrode is formed of nanometer indium tin oxide and the first upper substrate, the second lower substrate, and the pixel electrode are electrically connected by nanometer indium tin oxide.

5. The TFT substrate as claimed in claim 1, wherein the second upper substrate and the Com trace are electrically connected by nanometer indium tin oxide.

6. A TFT (Thin-Film Transistor) substrate, comprising: first and second sharing capacitors that are connected in parallel, a pixel electrode, and a Com trace, wherein the first sharing capacitor comprises a first upper substrate, a first lower substrate opposite to the first upper substrate, and a first semiconductor layer between the first upper substrate and the first lower substrate; the second sharing capacitor comprises a second upper substrate, a second lower substrate opposite to the second upper substrate, and a second semiconductor layer between the second upper substrate and the second lower substrate; the first upper substrate of the first sharing capacitor and the second lower substrate of the second sharing capacitor are electrically connected to the pixel electrode; and the second upper substrate of the second sharing capacitor is electrically connected to the Com trace; and
wherein the first upper substrate and the second upper substrate are formed of metal at the same time and the first lower substrate, the second lower substrate, and the Com trace are formed of metal at the same time.

7. The TFT substrate as claimed in claim 6, wherein the first semiconductor layer and the second semiconductor layer are formed at the same time and the first semiconductor layer and the second semiconductor layer both comprise a gate insulation layer and an amorphous silicon layer.

8. The TFT substrate as claimed in claim 6, wherein the pixel electrode is formed of nanometer indium tin oxide and the first upper substrate, the second lower substrate, and the pixel electrode are electrically connected by nanometer indium tin oxide.

9. The TFT substrate as claimed in claim 6, wherein the second upper substrate and the Com trace are electrically connected by nanometer indium tin oxide.

10. A liquid crystal display panel, comprising: a TFT (Thin-Film Transistor) substrate, a CF (Color Filter) substrate opposite to and laminated to the TFT substrate, and a liquid crystal layer arranged between the TFT substrate and the CF substrate, wherein the TFT substrate comprises first and second sharing capacitors that are connected in parallel, a pixel electrode, and a Com trace; the first sharing capacitor comprises a first upper substrate, a first lower substrate opposite to the first upper substrate, and a first semiconductor layer between the first upper substrate and the first lower substrate; the second sharing capacitor comprises a second upper substrate, a second lower substrate opposite to the second upper substrate, and a second semiconductor layer between the second upper substrate and the second lower substrate; the first upper substrate of the first sharing capacitor and the second lower substrate of the second sharing capacitor are electrically connected to the pixel electrode; and the second upper substrate of the second sharing capacitor is electrically connected to the Com trace.

11. The liquid crystal display panel as claimed in claim 10, wherein the first upper substrate and the second upper substrate are formed of metal at the same time and the first lower substrate, the second lower substrate, and the Com trace are formed of metal at the same time.

12. The liquid crystal display panel as claimed in claim 10, wherein the first semiconductor layer and the second semiconductor layer are formed at the same time and the first semiconductor layer and the second semiconductor layer both comprise a gate insulation layer and an amorphous silicon layer.

13. The liquid crystal display panel as claimed in claim 10, wherein the pixel electrode is formed of nanometer indium tin oxide and the first upper substrate, the second lower substrate, and the pixel electrode are electrically connected by nanometer indium tin oxide.

14. The liquid crystal display panel as claimed in claim 10, wherein the second upper substrate and the Com trace are electrically connected by nanometer indium tin oxide.
